(19) United States
(12) Patent Application Publication
(10) Pub. No.: US 2002/0079540 A1
(43) Pub. Date: Jun. 27, 2002

(54) Diode junction based electrostatic discharge (ESD) protection structure

(75) Inventors: Vladislav Vashchenko, Fremont, CA (US); Alexei Sadovnikov, Sunnyvale, CA (US)

Correspondence Address: PILLSBURY WINTHROP LLP, DOCKET/CALENDAR DEPARTMENT, 50 FREMONT STREET, SAN FRANCISCO, CA, 94105-2230, US

(73) Assignee: National Semiconductor Corporation

(21) Appl. No.: 09/747,848

(22) Filed: Dec. 21, 2000

(51) Int. Cl. H01L 23/62

(52) U.S. Cl. 257/355

(57) ABSTRACT

An ESD protection structure for use in high speed (e.g., 5-7 GHz RF frequency) CMOS and BiCMOS ICs that has a low leakage current and a low equivalent capacitance. The ESD protection structure can be manufactured using conventional processes and includes a semiconductor substrate of a first conductivity type (e.g., a P− epitaxial silicon semiconductor substrate) with a well region of a second conductivity type (e.g., an N− well region) disposed therein. The structure also includes a first region of the first conductivity type (e.g., a P+ first region) disposed in the well region on the semiconductor substrate, as well as a second region of the second conductivity type (e.g., an N+ second region) disposed in and on the semiconductor substrate and spaced apart from the first region. Furthermore, an electrical isolation region is disposed in the semiconductor substrate between the first region and the second region. The ESD protection structure exhibits diode-like electrical behavior with the first region serving as an anode and the second region serving as a cathode, including a low equivalent capacitance and low reverse bias leakage current.

### BACKGROUND OF THE INVENTION

1. Field of the Invention

The present invention relates to semiconductor device structures and, in particular, to Electrostatic Discharge (ESD) protection structures for use with integrated circuits.

2. Description of the Related Art

Electrostatic Discharge (ESD) protection devices are commonly employed in an integrated circuit (IC) to protect electronic devices in the IC from spurious pulses of excessive voltage (e.g., an ESD event, Human Body Model [HBM] event, or Electrical Overstress [EOS] event). See, for example, S. M. Sze, Electrostatic Discharge Damage, in VLSI Technology, Second Edition, 648-650 (McGraw Hill, 1988). A variety of conventional ESD protection devices that make extensive use of diodes, metal-oxide-semiconductor field effect transistors (MOSFETs) and bipolar transistors are known in the field.

FIG. 1 illustrates a conventional N-well diode ESD protection structure 10 for use with CMOS and BiCMOS ICs. The conventional N-well diode ESD bottom contact (not shown). Formed in the P− epitaxial silicon substrate 12 are an N-well region 14, a P+ region 16 and an N+ contact region 18. An electrical isolation region (e.g., a shallow trench isolation [STI] region or a LOCOS isolation region) 20 separates the P+ region 16 from the N+ contact region 18. One skilled in the art will recognize that the P+ region 16 and N+ contact region 18 essentially serve as the anode and cathode of the N-well diode ESD protection structure, respectively.

Since the conventional N-well diode ESD protection structure 10 is manufactured using conventional CMOS or BiCMOS IC processes, the dopant concentration of the N-well region 14 is typically greater than 2×10¹⁷ atoms/cm³. The equivalent capacitance of the conventional N-well diode ESD protection structure 10 is determined by the dopant concentration gradient across the diode junction between the P+ region 16 and the N-well region 14. Since the N-well region 14 has a significant dopant concentration, the equivalent capacitance of conventional N-well diode ESD protection structure 10 is relatively high (e.g., 100 femtoF per 50 microns of width). Conventional N-well diode ESD protection structures do, however, possess low reverse bias leakage current characteristics.

FIG. 2 illustrates a conventional P− epi diode ESD protection structure 30 for use with CMOS and BiCMOS ICs. The conventional P− epi diode ESD protection structure 30 includes a P− epitaxial silicon substrate 32 with a P+ bottom contact (not shown). Formed in the P− epitaxial silicon substrate 32 are an N+ region 34 and a P+ contact region 36. An electrical isolation region (e.g., an STI region or a LOCOS isolation region) 38 separates the N+ region 34 from the P+ contact region 36. One skilled in the art will recognize that the P+ contact region 36 and N+ region 34 essentially serve as the anode and cathode of the conventional P− epi diode ESD protection structure 30, respectively.

Since the conventional P− epi diode ESD protection structure 30 is manufactured using conventional CMOS or BiCMOS ICs processes, the dopant concentration of the P− epitaxial silicon substrate 32 is approximately 5×10¹⁵ atoms/cm³. The equivalent capacitance of the conventional P− epi diode ESD protection structure 30 is determined by the dopant concentration gradient across the diode junction between the P− epitaxial silicon substrate 32 and the N+ region 34. Since the P− epitaxial silicon substrate 32 has a relatively low dopant concentration, the equivalent capacitance of the conventional P− epi diode ESD protection structure 30 is also relatively low. However, conventional P− epi diode ESD protection structure 30 exhibits high reverse bias leakage current due to the presence of the grounded (via the P+ bottom contact) P− epitaxial silicon substrate 32.

Further descriptions of conventional ESD protection structures are available in G. Croft and J. Bernier, ESD Protection Techniques for High Frequency Integrated Circuits, Microelectronics Reliability 38, 1681-1689 (1998); J. Z. Chen et al., Design and Layout of a High ESD Performance NPN Structure for Submicron BiCMOS/Bipolar Circuits, 34^{th} Annual IEEE International Reliability Physics Symposium Proceedings, 227-232(1996); J. C. Bernier et al., A Process Independent ESD Design Methodology, IEEE International Symposium on Circuits and Systems Proceedings 1, 218-221 (1999); W. D. Mack et al., New ESD Protection Schemes for BiCMOS Processes with Application to Cellular Radio Designs, IEEE International Symposium on Circuits and Systems 6, 2699-2702(1992); H. Hyatt et al., Optimizing the Performance of ESD Circuit Protection Devices, EOS/ESD Symposium, 41-47 (2000); and Yu Wang et al., Electrothermal Modeling of ESD Diodes in Bulk-Si and SOI Technologies, EOS/ESD Symposium, 430-436(2000), each of which is hereby fully incorporated by reference.

The ESD protection of high-speed (e.g., high frequency RF) CMOS and BICMOS ICs is difficult since these ICs must operate under low signal degradation (i.e., low equivalent capacitance) and low leakage current conditions. Conventional N-well and P− epi diode ESD protection structures (such as those shown in FIGS. 1 and 2) are, therefore, not suitable for use with high frequency CMOS and BiCMOS ICs due to their high equivalent capacitance and high leakage current, respectively. Furthermore, the use of additional process steps (e.g., additional dopant ion implant and masking steps) to produce an ESD protection structure for use with high speed CMOS and BiCMOS ICs is expensive and hence, not desirable.

Still needed in the field, therefore, is an ESD protection structure for use in high frequency (e.g., RF) CMOS and BiCMOS ICs that has both a low leakage current and a low equivalent capacitance. The ESD protection structure should also be manufacturable using conventional CMOS and BiCMOS processes.

### SUMMARY OF THE INVENTION

The present invention provides an ESD protection structure for use in high speed (e.g., 5-7 GHz and above RF frequency) CMOS and BiCMOS ICs that has both a low leakage current and a low equivalent capacitance. ESD protection structures according to the present invention are also manufacturable using conventional CMOS and BiCMOS processes.

ESD protection structures according to the present invention include a semiconductor substrate of a first conductivity type (e.g., a P− epitaxial silicon semiconductor substrate) with a well region of a second conductivity type (e.g., an N− well region) disposed therein. The ESD protection structures also include a first region of the first conductivity type (e.g., a P+ first region) disposed in the well region on the semiconductor substrate and a second region of the second conductivity type (e.g., a N− second region) disposed in and on the semiconductor substrate and spaced apart from the first region. Furthermore, an electrical isolation region is disposed in the semiconductor substrate between the first region and the second region.

ESD protection structures according to the present invention exhibit diode-like electrical behavior, including a low equivalent capacitance and low reverse bias leakage current, with the first region serving as an anode and the second region serving as a cathode. The low equivalent capacitance is provided by a diode junction between the first region and the well region. The low reverse bias leakage current is provided by the diode junction between the second region and the semiconductor substrate. ESD protection structures according to the present invention can be manufactured using conventional CMOS and BiCMOS processes and as part of an IC along with associated CMOS and BiCMOS transistors.

### BRIEF DESCRIPTION OF THE DRAWINGS

A better understanding of the features and advantages of the present invention will be obtained by reference to the following detailed description that sets forth illustrative embodiments, in which the principles of the invention are utilized, and the accompanying drawings (in which like numerals are used to designate like elements), of which:

FIG. 1 is a cross-sectional view of a conventional N-well diode ESD protection structure.

FIG. 2 is a cross-sectional view of a conventional P− epi diode ESD protection structure.

FIG. 3 is a cross-sectional view of an ESD protection structure according to the present invention.

FIG. 4 is a perspective view of the ESD protection structure of FIG. 3.

FIGS. 5A-5D are I-V graphs depicting the forward and reverse DC characteristics of an ESD protection structure according to the present invention and a conventional N-well diode ESD protection structure.

FIG. 6 is a graph depicting the RF characteristics of an ESD protection structure according to the present invention and a conventional N-well diode ESD protection structure.

FIG. 7 is a graph depicting the HBM pulse transient characteristics of an ESD protection structure according to the present invention and a conventional N-well diode ESD protection structure.

FIGS. 8A and 8B are electrical schematics illustrating ESD protection structures according to the present invention (depicted using a conventional diode symbol) configured between an input/output (I/O) line and ground (GND) (FIG. 8A) and configured between a V_{DD}+ line and a differential amplifier and between a V_{DD}− line and a differential amplifier (FIG. 8B).

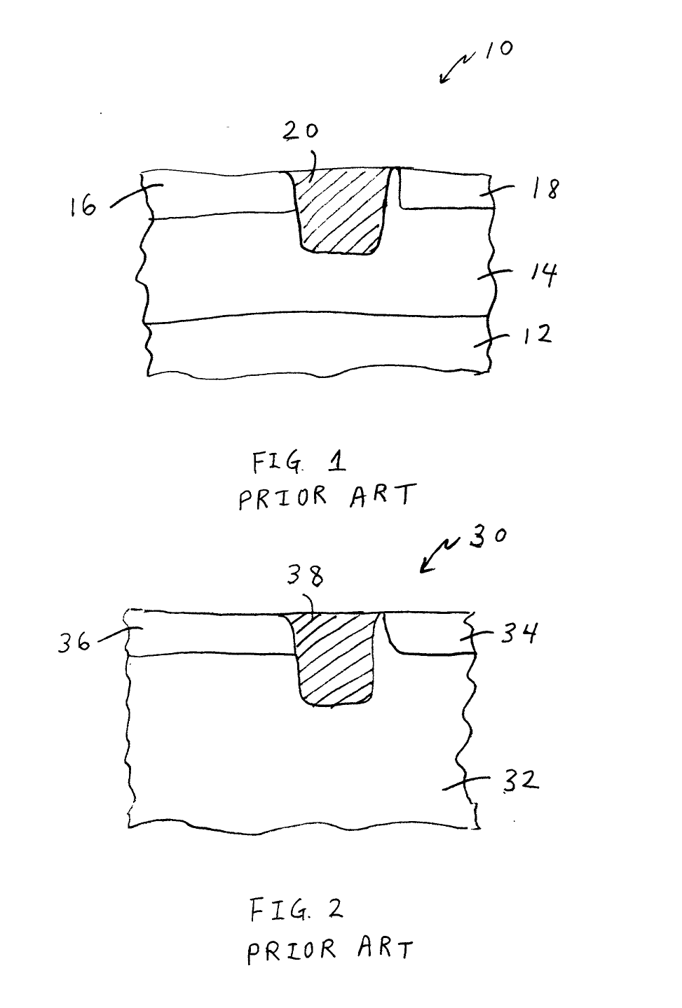

### DETAILED DESCRIPTION OF THE INVENTION

To be consistent throughout the present specification and for clear understanding of the present invention, the following definitions are provided for terms used therein:

The terms “dopant” and “dopants” refer to donor and acceptor impurity atoms (e.g., boron [B], phosphorous [P], arsenic [As] and indium [In]), which are intentionally introduced into a semiconductor substrate (e.g., a silicon wafer) in order to change the substrate's charge-carrier concentration. See, R. S. Muller and T. I. Kamins, Device Electronics for Integrated Circuits 2nd Edition, 11-14 (John Wiley and Sons, 1986) for a further description of dopants.

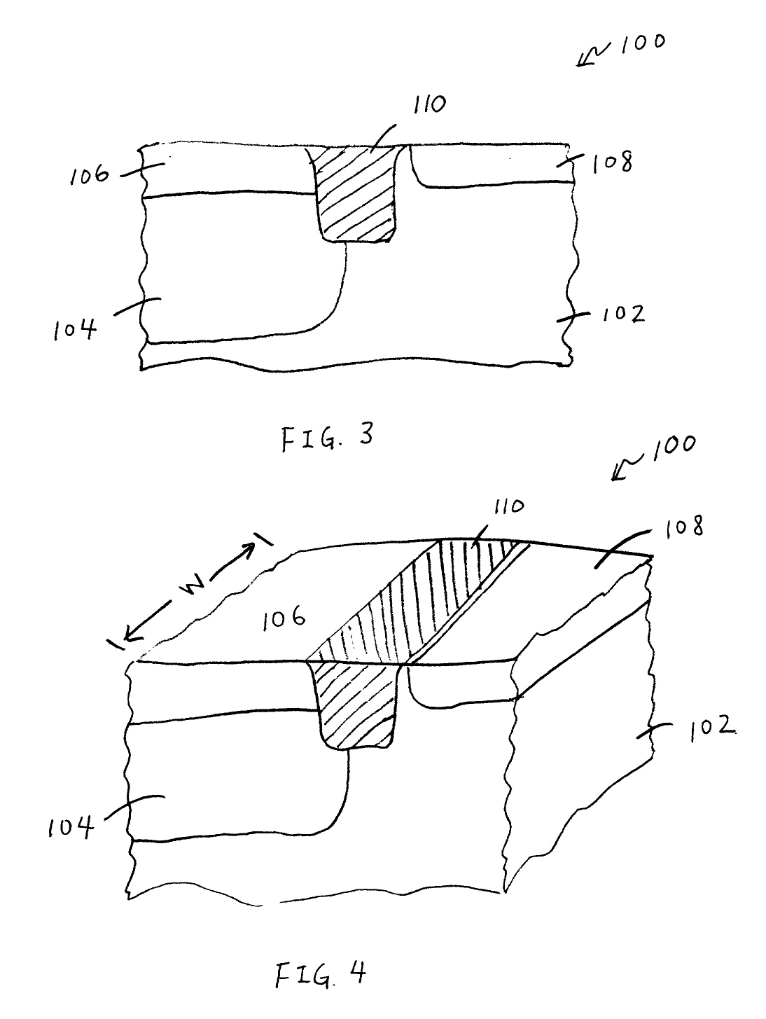

FIGS. 3 and 4 illustrate an ESD protection structure 100 for use with high speed CMOS and BiCMOS integrated circuits (ICs) according to the present invention. ESD protection structure 100 includes a P− epitaxial silicon semiconductor substrate 102. The minus (−) sign indicates that the net P type dopant concentration in the P− epitaxial silicon semiconductor substrate 102 is relatively low (i.e., the substrate is lightly doped), for example 5×101¹⁵ atoms/cm³. If desired, a P+ bottom contact or other contact means (not shown) to the P− epitaxial silicon semiconductor substrate can be provided.

ESD protection structure 100 also includes an N− well region 104 disposed in the P− epitaxial silicon semiconductor substrate 102. The minus (−) sign indicates that the net N-type dopant concentration in the N− well region 104 is relatively low, for example 5×10¹⁷ atoms/cm³. The depth of the N− well region 104 depends on the semiconductor manufacturing process technology employed to create the ESD protection structure. However, for an 0.18 micron CMOS or BiCMOS technology, the N− well region has a maximum depth below the surface of the P− epitaxial silicon semiconductor substrate 102 of, for example, approximately 1.25 microns.

Also included in ESD protection structure 100 is a P+ first region 106 disposed in the N− well region 104 on the P− epitaxial silicon semiconductor substrate 102. The plus (+) sign indicates that the P+ first region 106 has a higher net dopant concentration than that of the P− epitaxial silicon semiconductor substrate 102. For example, the P+ first region 106 can have a maximum net dopant concentration of 5×10²⁰ atoms/cm³. The depth of P+ first region 106 depends on the semiconductor manufacturing process technology employed to create the ESD protection structure 100. However, for an 0.18 micron CMOS or BiCMOS technology, the P+ first region 106 has a maximum depth below the surface of the P− epitaxial silicon semiconductor substrate 102 of, for example, approximately 0.25 microns.

ESD protection structure 100 also includes an N+ second region 108 disposed in and on the P− epitaxial silicon semiconductor substrate 102 and spaced apart from the P+ first region 106. The plus (+) sign indicates that the N+ second region 108 has a higher net dopant concentration than that of the N− well region 104. For example, the N+ second region 108 can have a maximum net dopant concentration of 5×10²⁰ atoms/cm³. For an 0.18 micron CMOS or BiCMOS technology, the N+ second region 108 has a maximum depth below the surface of the P− epitaxial silicon semiconductor substrate 102 of, for example, approximately 0.25 microns.

An electrical isolation region 110 disposed in the P− epitaxial silicon semiconductor substrate 102 between the P+ first region 106 and the N+ second region 108 is further included in ESD protection structure 100. The spacing created by the electrical isolation region 110 depends on the manufacturing technology but is, for example, approximately 0.5 microns. Electrical isolation region 110 can take the form, for example, of a shallow trench isolation (STI) region or a LOCOS isolation region.

FIG. 4 illustrates how the P+ first region 106 and N+ second region 108 can be formed as “strips” alongside of the electrical isolation region 110. The width (W) of these strips is a factor in determining the ESD protection capability of the ESD protection structure 100. To provide protection against a 1.5 kV human body model (HBM) pulse, the width would typically be around 50 microns.

The structural arrangement of ESD protection structure 100 inherently provides three diode junctions, namely: (i) a diode junction between the P+ first region 106 and the N− well region 104; (ii) a diode junction between the N+ second region 108 and the P− epitaxial silicon semiconductor substrate 102; and (iii) a diode junction between the P− epitaxial silicon semiconductor substrate 102 and the N− well region 104. This structural arrangement can be thought of as a unique variant of a PNPN thyristor structure that provides ESD protection capability by the distinctive addition of a lightly doped P-epitaxial silicon substrate. However, the presence of the lightly doped P− epitaxial silicon substrate, and in particular the relatively narrow portion of the P-epitaxial silicon semiconductor substrate between the N− well region and the N+ second region, alters typical thyristor behavior in such a manner that ESD protection structures according to the present invention exhibit novel diode-like behavior. In this respect, ESD protection structures according to the present invention can be considered diode junction based ESD protection structures with the P+ first region essentially serving as an anode and the N+ second region essentially serving as a cathode.

Further, the diode junction between the P− epitaxial semiconductor substrate (which is relatively lightly doped) and the N− well region creates a large space charge region, thereby decreasing the equivalent capacitance of the ESD protection structure. Furthermore, the N− well region prevents high leakage current when the ESD protection structure is operated under reverse bias with a P+ bottom contact. In essence, ESD protection structures according to the present invention possess a combination of the low leakage of a conventional N-well diode ESD protection structure and the low equivalent capacitance of a Conventional P− epitaxial diode ESD protection structure.

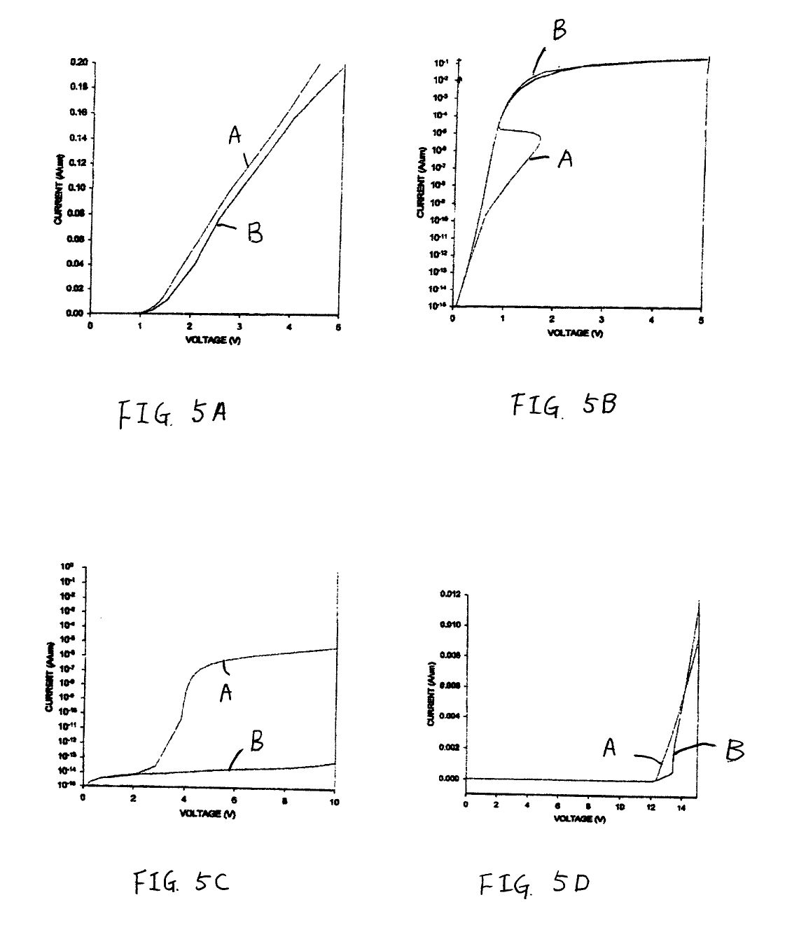

FIGS. 5A-5D are graphs of current (y-axis) versus voltage (x-axis) illustrating the operation of an ESD protection structure according to the present invention (curves labeled A), in comparison to a conventional N-well diode protection structure (curves labeled B). FIGS. 5A and 5B illustrate the forward bias isothermal characteristics of using linear (FIG. 5A) and log (FIG. 5B) scales. FIGS. 5C and 5D illustrate the reverse bias isothermal characteristics of using linear (FIG. 5C) and log (FIG. 5D) scales. FIGS. 5A through 5D illustrate that ESD protection structures according to the present invention possess low leakage characteristics.

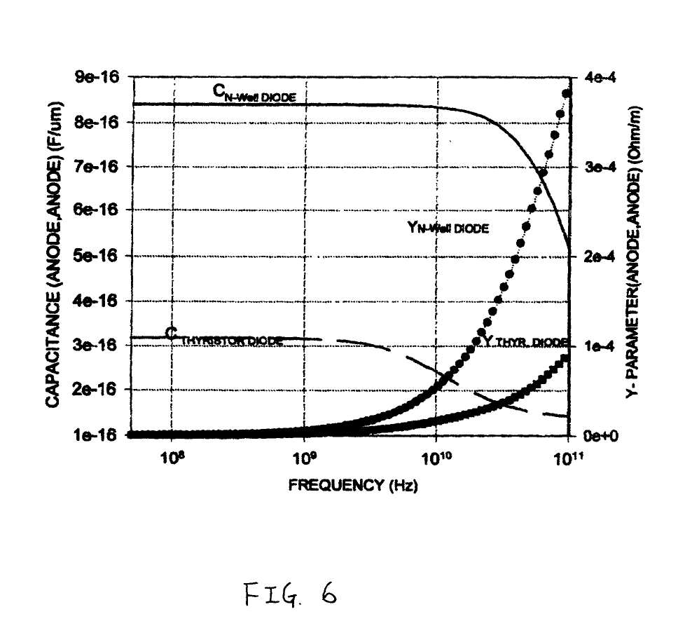

FIG. 6 is a graph illustrating the capacitance and Y-parameter (which is related to impedance) of an ESD protection structure according to the present invention (labeled as a “thyristor diode”), in comparison to a conventional N-well diode protection structure (labeled as an “N− Well Diode”) as a function of the applied RF frequency. FIG. 6 illustrates that the capacitance of ESD protection structures according to the present invention is 2-3 times less than that of the conventional N− well diode protection structure. This lower equivalent capacitance provides ESD protection structures according to then present invention with a critical advantage when used with high-frequency 5-7 GHz analog IC's. In addition, the Y-parameter of the ESD structure according to the present invention is lower that that of the conventional N-well diode, indicating a beneficially lower load on the RF signal.

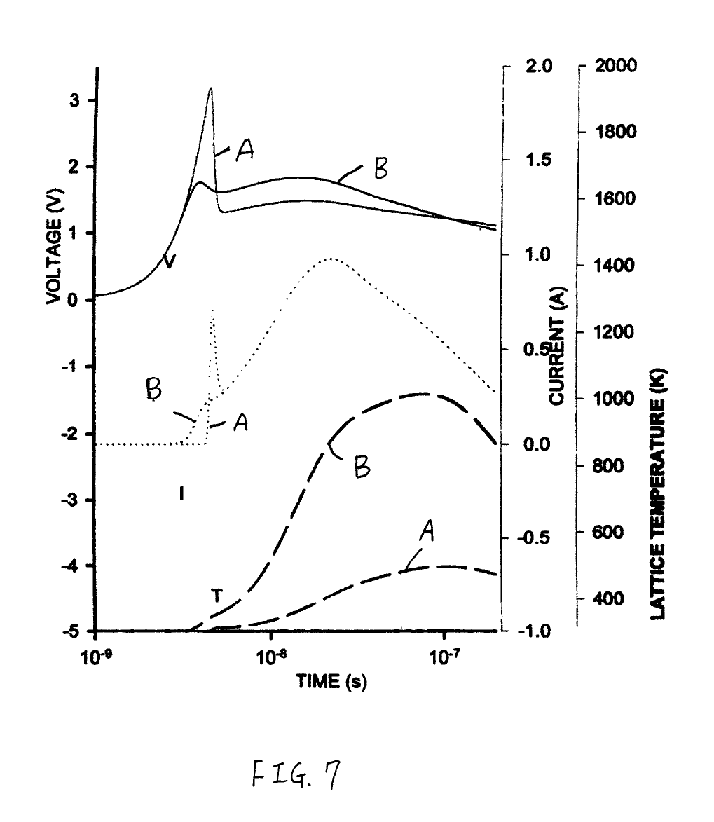

FIG. 7 is a graph illustrating the voltage (V), current (I) and lattice temperature (T) behavior for an ESD protection structure according to the present invention (curves labeled A) and a conventional N-well diode protection structure (curves labeled B) during a 1.5 kV Human Body Model (HBM) pulse. FIG. 7 indicates that ESD protection structures according to the present invention provide for a decreased lattice temperature during an ESD event.

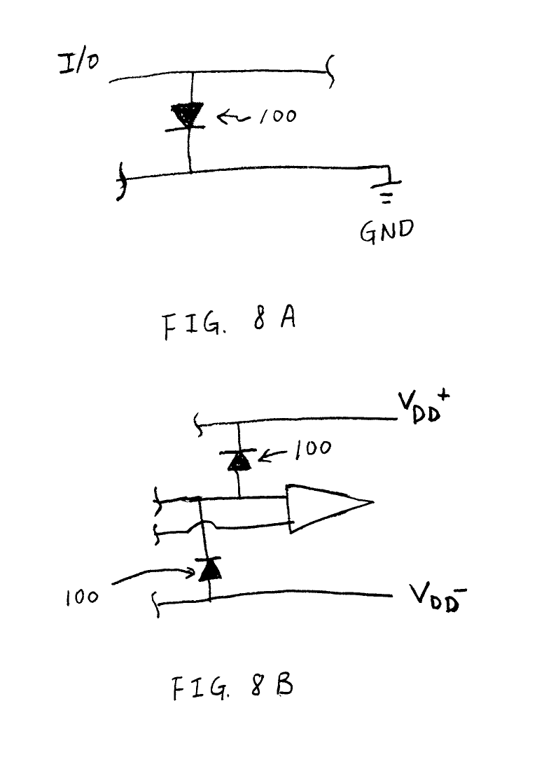

One skilled in the art will recognize that ESD protection structures according to the present invention can be configured in a variety of ways (similar to a conventional diode structure) to provide ESD protection to an integrated circuit. For example, FIGS. 8A and 8B are electrical schematics illustrating ESD protection structures according to the present invention (depicted using a conventional diode symbol) configured to provide ESD protection between an input/output (I/O) line and ground (GND) (FIG. 8A) and configured to provide ESD protection between a V_{DD}+ line and a differential amplifier and between a V_{DD}− line and a differential amplifier (FIG. 8B).

One skilled in the art will also recognize that ESD protection structures according to the present invention can be easily integrated into CMOS and BiCMOS integrated circuits, including high frequency (e.g., 5 to 7 GHz) integrated circuits and that the ESD protection structure can be formed as a monolithic whole along with the CMOS and/or BiCMOS transistors on a single semiconductor substrate (e.g., a silicon or SOI substrate)

It should be understood that various alternatives to the embodiments of the invention described herein may be employed in practicing the invention. It is intended that the following claims define the scope of the invention and that structures within the scope of these claims and their equivalents be covered thereby.

What is claimed is:

1. An ESD protection structure for an integrated circuit comprising:
a semiconductor substrate of a first conductivity type;
a well region of a second conductivity type disposed in the semiconductor substrate;
a first region of the first conductivity type disposed in the well region on the semiconductor substrate;
a second region of the second conductivity type disposed in and on the semiconductor substrate and spaced apart from the first region; and
an electrical isolation region disposed in the semiconductor substrate between the first region and the second region.

2. The ESD protection structure of claim 1, wherein the first conductivity type is P-type and the second conductivity type is N-type.

3. The ESD protection structure of claim 2, wherein the maximum dopant concentration of the semiconductor substrate is less than the maximum dopant concentration of the first region and the maximum dopant concentration of the well region is less than the maximum dopant concentration of the second region.

4. The ESD protection structure of claim 3, wherein the dopant concentration of the semiconductor substrate is 5×10¹⁵ atoms/cm³, the maximum dopant concentration of the well region is 2×10¹⁷ atoms/cm³, the maximum dopant concentration of the first region is 5×10²⁰ atoms/cm³, and the maximum dopant concentration of the second region is 5×10²⁰ atoms/cm³.

5. The ESD protection structure of claim 1, wherein the electrical isolation region is a shallow trench isolation region.

6. The ESD protection structure of claim 1, wherein the semiconductor substrate comprises a P− epitaxial silicon layer.

7. The ESD protection structure of claim 6, wherein the P− epitaxial silicon layer has a dopant concentration no greater than 5×10¹⁵ atoms/cm³.

8. The ESD protection structure of claim 1 configured between an input/output line of the integrated circuit and GND.

9. The ESD protection structure of claim 1 configured between a V_{DD} line of the integrated circuit and a differential amplifier of the integrated circuit.

10. The ESD protection structure of claim 1 further comprising a bottom contact to the semiconductor substrate.

11. An ESD protection structure for use with RF frequency integrated circuits comprising:
a P− epitaxial silicon semiconductor substrate;
an N− well region disposed in the semiconductor substrate;
a P+ first region disposed in the N-well region on the P− epitaxial silicon semiconductor substrate;
an N+ second region disposed in and on the P− epitaxial silicon semiconductor substrate and spaced apart from the P+ first region; and
an electrical isolation region disposed in the P− epitaxial silicon semiconductor substrate between the P+ first region and the N+ second region.
